(19) United States
(12) Patent Application Publication
(10) Pub. No.: US 2021/0172085 A1
(43) Pub. Date: Jun. 10, 2021

(54) SiC SUBSTRATE AND SiC SINGLE CRYSTAL MANUFACTURING METHOD

(71) Applicant: SHOWA DENKO K.K., Tokyo (JP)

(72) Inventor: Akihiro MATSUSE, Chichibu-shi (JP)

(73) Assignee: SHOWA DENKO K.K., Tokyo (JP)

(21) Appl. No.: 17/113,220

(22) Filed: Dec. 7, 2020

(30) Foreign Application Priority Data
Dec. 9, 2019 (JP) 2019-222344

(51) Int. Cl. C30B 29/36; C30B 23/06

(52) U.S. Cl. CPC C30B 29/36; C30B 23/066

(57) ABSTRACT

A SiC substrate contains tantalum or niobium of which the content is equal to or more than 3×10¹⁴ cm⁻³ and equal to or less than 1×10¹⁵ cm⁻³, and nitrogen of which the content is equal to or more than 1×10¹⁶ cm ⁻³ and equal to or less than 1×10²⁰ cm⁻³.

### BACKGROUND OF THE INVENTION

### Field of the Invention

The present invention relates to a SiC substrate and a SiC single crystal manufacturing method.

The application is based on Japanese Patent Application No. 2019-222344 filed on Dec. 9, 2019, the content of which is incorporated herein by reference.

### Description of Related Art

In silicon carbide (SiC), dielectric breakdown electric field is larger by one order of magnitude and a band gap is three times larger than those of silicon (Si). In addition, silicon carbide (SiC) has characteristics such as a thermal conductivity which is three times higher than that of silicon (Si). For this reason, silicon carbide (SiC) is expected to be applied to power devices, high frequency devices, high temperature operation devices, and the like. Thus, in recent years, SiC epitaxial wafers have been used for the semiconductor devices as referred to above.

SiC epitaxial wafers are obtained by laminating an epitaxial layer on the surface of a SiC substrate cut out from a SiC ingot. Hereinafter, a substrate before laminating an epitaxial layer will be referred to as a SiC substrate, and a substrate after laminating an epitaxial layer will be referred to as a SiC epitaxial wafer.

In recent years, improvements in the quality of SiC substrates and productivity have been required with market demands. For example, Patent Document 1 discloses a silicon carbide single crystal containing a metal element other than a light metal having an atomic radius larger than that of silicon. Since a metal element other than a light metal having an atomic radius larger than that of silicon is added, lattice distortion in a crystal is eliminated, and the quality of a silicon carbide single crystal is improved.

### Patent Documents

[Patent Document 1] Japanese Patent No. 3876628

### SUMMARY OF THE INVENTION

However, even when a metal element in the range disclosed in Patent Document 1 is added, carbonization or polymorphism may occur in a SiC substrate. Here, carbonization refers to a state where some Si and C are not combined and C separates out alone, and polymorphism refers to the mixing of crystals of different polytypes. SiC has polytypes such as 3C—SiC, 4H—SiC, 6H—SiC, and 15R—SiC.

The present invention is contrived in view of the above-described circumstances, and an object thereof is to provide a SiC substrate having high purity and less carbonization and polymorphism, and a SiC single crystal manufacturing method.

The inventors have found that a large fluctuation in a C/Si ratio of a sublimated gas is one of the causes of carbonization and polymorphism when manufacturing a SiC ingot that is a base of a SiC substrate. That is, the inventors have found that it is not sufficient to only eliminate lattice distortion as disclosed in Patent Document 1 in order to obtain a SiC substrate having high purity and less carbonization and polymorphism, and more rigorous control is required. That is, the present invention provides the following means in order to solve the above-described problem.

(1) A SiC substrate according to a first aspect includes tantalum or niobium of which a content is equal to or more than 3×10¹⁴ cm⁻³ and equal to or less than 1×10¹⁵ cm⁻³, and nitrogen of which a content is equal to or more than 1×10¹⁶ cm⁻³ and equal to or less than 1×10²⁰ cm⁻³.

(2) In the SiC substrate according to the above-described aspect, a content of aluminum may be less than 1×10¹⁶ cm⁻³.

(3) In the SiC substrate according to the above-described aspect, a content of boron may be less than 1×10¹⁶ cm⁻³.

(4) In the SiC substrate according to the above-described aspect, a content of a heavy metal element may be less than 1×10¹⁴ cm⁻³.

(5) In the SiC substrate according to the above-described aspect, content ratio of tantalum or niobium may differ between those on a first surface and a second surface perpendicular to a thickness direction.

(6) The SiC substrate according to the above-described aspect may further include a first surface and a second surface perpendicular to a thickness direction, in which a content ratio of tantalum or niobium may decrease toward the second surface from the first surface.

(7) A SiC single crystal manufacturing method according to a second aspect is a SiC single crystal manufacturing method using a sublimation method in which a single crystal is grown by recrystallizing a gas sublimated from a raw material on a surface of a seed crystal, and the raw material contains tantalum or niobium.

(8) In the SiC single crystal manufacturing method according to the above-described aspect, a concentration of tantalum or niobium in the raw material may be substantially constant.

(9) In the SiC single crystal manufacturing method according to the above-described aspect, a concentration of tantalum or niobium on a surface of the raw material which faces the seed crystal may be lower than a concentration of tantalum or niobium inside the raw material.

(10) In the SiC single crystal manufacturing method according to the above-described aspect, the tantalum or niobium may be deposited on a surface of a SiC raw material.

(11) In the SiC single crystal manufacturing method according to the above-described aspect, a concentration of tantalum or niobium on a surface of the raw material which faces the seed crystal may be higher than a concentration of tantalum or niobium inside the raw material.

(12) In the SiC single crystal manufacturing method according to the above-described aspect, a concentration of tantalum or niobium at the center may be higher than a concentration of tantalum or niobium in the outer side when the raw material is seen in a plan view.

(13) In the SiC single crystal manufacturing method according to the above-described aspect, an amount of the tantalum or niobium added may be equal to or more than 1 wt % and equal to or less than 8 wt %.

(14) A SiC single crystal manufacturing method according to a third aspect is a SiC single crystal manufacturing method using a sublimation method in which a single crystal is grown by recrystallizing a gas sublimated from a raw material on a surface of a seed crystal, and the raw material is sublimated on the environment in which powder or plate-like tantalum or niobium is positioned between the raw material and the seed crystal.

(15) The SiC single crystal manufacturing method according to the above-described aspect is a SiC single crystal manufacturing method using a crucible including a protrusion portion that protrudes toward an axial center of the crucible from an inner surface, and the raw material may be sublimated on the environment in which the powder or plate-like tantalum or niobium is positioned on the protrusion portion.

A SiC substrate according to the above-described aspect has high purity and less carbonization and polymorphism.

### BRIEF DESCRIPTION OF THE DRAWINGS

FIG. 1 is a schematic cross-sectional view of a manufacturing device for describing a SiC substrate manufacturing method according to the present embodiment.

FIG. 2 is a schematic cross-sectional view of a manufacturing device for describing a SiC substrate manufacturing method according to a modification example of the present embodiment.

### DETAILED DESCRIPTION OF THE INVENTION

Hereinafter, a SiC substrate and the like according to the present embodiment will be described in detail with appropriate reference to the drawings. In some cases, in the drawings used in the following description, characteristic portions are illustrated at an enlarged scale for convenience of easy understanding of characteristics, and the dimensional ratios and the like of the respective components are not necessarily the same as the actual ones. In the following description, materials, dimensions, and the like are merely exemplary, do not limit the present invention, and can be appropriately modified within a range not departing from the scope of the present invention.

A SiC substrate according to the present embodiment contains tantalum or niobium and nitrogen. Nitrogen is an n-type dopant. Since the SiC substrate contains nitrogen, a resistance value of the SiC substrate is low. The content of nitrogen is equal to or more than 1×10¹⁶ cm⁻³ and equal to or less than 1×10²⁰ cm⁻³. The content of nitrogen is preferably equal to or more than 1×10¹⁷ cm⁻³ and equal to or less than 1×10¹⁹ cm⁻³, and more preferably equal to or more than 1×10¹⁸ cm⁻³ and equal to or less than 1×10¹⁹ cm⁻³. When the content of nitrogen falls within this range, a SiC substrate having low resistance and excellent crystallinity is obtained.

Tantalum or niobium is included as an elemental substance or in a carbonized state in the SiC substrate. Both tantalum and niobium similarly belong to Group 5, have similar electronic states in the outermost shells thereof, and have a property of easily combining with carbon. Tantalum and niobium play a role in adjusting the abundance ratio of carbon during crystal growth.

The content ratio of tantalum or niobium is equal to or more than 3×10¹⁴ cm⁻³ and equal to or less than 1×10¹⁵ cm⁻³. The content ratio of tantalum or niobium is preferably equal to or more than 5×10¹⁴ cm⁻³ and equal to or less than 8×10¹⁴ cm⁻³.

The content ratio of tantalum or niobium may be the same as or different in a thickness direction. For example, the content ratio of tantalum or niobium may differ between those on a first surface and a second surface of the SiC substrate, or may decrease toward the second surface from the first surface. The first surface and the second surface of the SiC substrate are surfaces perpendicular to the thickness direction of the SiC substrate.

In the SiC substrate according to the present embodiment, the content of aluminum may be less than 1×10¹⁶ cm⁻³. Further, in the SiC substrate according to the present embodiment, the content of boron may be less than 1×10¹⁶ cm ³. Aluminum and boron function as acceptors in the SiC substrate. In an n-type semiconductor substrate, a SiC substrate containing less aluminum and boron has high purity and is advantageous in manufacturing a SiC epitaxial wafer and a SiC device.

In addition, it is preferable that the amount of heavy metal elements in the SiC substrate according to the present embodiment is small. A heavy metal element is, for example, vanadium, tungsten, neodymium, or the like. The content of heavy metal elements may be, for example, less than 1×10¹⁴ cm⁻³.

Subsequently, a method of manufacturing a SiC substrate according to the present embodiment will be described. The method of manufacturing a SiC substrate according to the present embodiment includes a SiC ingot growth step and a SiC ingot cutting step. The SiC substrate is obtained by slicing a SiC ingot.

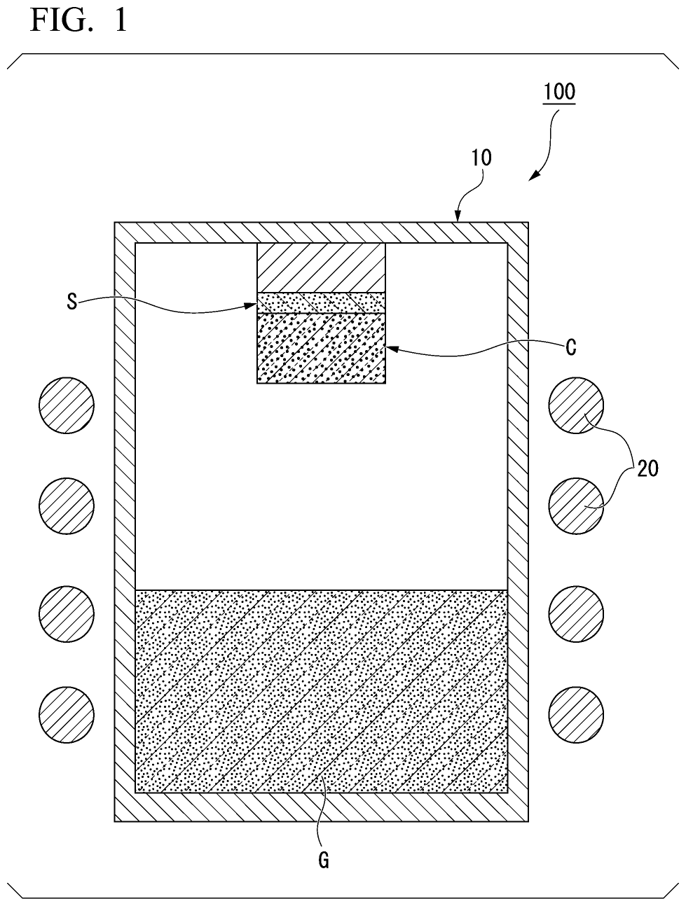

FIG. 1 is a cross-sectional view of a manufacturing device for describing a SiC substrate manufacturing method according to the present embodiment. FIG. 1 illustrates an example of a SiC ingot manufacturing step using a sublimation method. A SiC ingot manufacturing device 100 illustrated in FIG. 1 includes a crucible 10 and coils 20. A raw material G is accommodated on the inner bottom surface of the crucible 10, and a seed crystal S is placed on a position facing the raw material G. The raw material G is heated by induction heating to be sublimated. The sublimated raw material G is recrystallized on the seed crystal S, whereby a single crystal C is grown. A SiC ingot is obtained by removing the single crystal C from the crucible 10.

In the SiC substrate manufacturing method according to the present embodiment, tantalum or niobium is added to the raw material G in the SiC ingot growth step. The raw material G is, for example, SiC powder. Tantalum or niobium is added as, for example, powder. The concentration of tantalum or niobium in the raw material G is, for example, substantially constant. In the present specification, the term “substantially constant” means that when the raw material G is divided into 10 parts in the height direction from the inner bottom surface of the crucible 10, any fluctuation in the concentration of tantalum or niobium in each of the separate regions is within 10%. A particle diameter of tantalum or niobium which is added is preferably within the range of a particle size distribution of the SiC powder. For example, the particle diameter of the SiC powder may be equal to or more than 0.01 mm and equal to or less than 2.0 mm, and the particle diameter of tantalum or niobium is equal to or more than 0.1 mm and equal to or less than 1.0 mm.

The amount of tantalum or niobium added is, for example, equal to or more than 1 wt % and equal to or less than 8 wt %, and preferably, equal to or more than 2 wt % and equal to or less than 6 wt %.

The single crystal C is obtained by recrystallizing gases sublimated from SiC. When the composition ratio of carbon in the sublimated gas is high, a portion of the single crystal C is carbonized. In addition, when the composition ratio of silicon in the sublimated gas is high, the crystal growth of 4H—SiC becomes unstable, which may result in polymorphism or may result in silicon droplets. A composition ratio (C/Si ratio) of silicon to carbon in the sublimated gas is not constant at all times but fluctuates. When the fluctuation is large, carbonization or polymorphism is likely to occur in the single crystal C.

The compositional ratio between silicon and carbon in the sublimated gas is adjusted when tantalum or niobium is added to the raw material G. For example, tantalum and niobium combine with carbon to prevent the composition ratio of carbon in the sublimated gas from being an excess.

When an appropriate amount of tantalum or niobium is added, a C/Si ratio is adjusted, whereby it is possible to prevent carbonization or polymorphism from occurring in the single crystal C. When the amount of tantalum or niobium is in excess, a silicon composition ratio in the sublimated gas is high, and there is greater polymorphism. When the amount of tantalum or niobium is small, a carbon composition ratio in the sublimated gas is high, and carbonization occurs. Tantalum or niobium combines with carbon and is incorporated into a SiC ingot in the state of tantalum carbide or niobium carbide.

According to the SiC ingot manufacturing method of the present embodiment, polymorphism and carbonization can be suppressed, and high-purity crystals are easily manufactured. Since the SiC substrate can be manufactured by slicing a SiC ingot, the manufactured SiC substrate also has high purity. In addition, the manufactured SiC substrate has high purity, which is stead in manufacturing a SiC epitaxial wafer and a SiC device.

Although a preferred embodiment of the present invention has been described in detail, the present invention is not limited to a specific embodiment, and various modifications and changes can be made without departing from the scope of the gist of the present invention recited in the claims.

For example, when tantalum or niobium is added to the raw material G, the abundance ratio of tantalum or niobium in the raw material does not need to be uniform in the entire raw material G. For example, the concentration of tantalum or niobium on the surface of the raw material G may be lower than that inside the raw material G. The vapor pressure of silicon is higher than the vapor pressure of carbon, and thus silicon is sublimated more easily than carbon at the initial stage of crystal growth. When the amount of tantalum or niobium sublimated at the initial stage of crystal growth increases, a silicon composition ratio in a sublimated gas increases, and thus polymorphism is more likely to occur. When the concentration of tantalum or niobium on the surface of the raw material G is low, the amount of tantalum or niobium sublimated at the initial stage of crystal growth is reduced. Since there is a tendency for the silicon composition ratio to be high in the initial stage of crystallization, a likelihood of polymorphism occurring is lowered due to the amount of carbon being adsorbed by tantalum or niobium being reduced. In this case, in the single crystal C which is subjected to crystal growth, the content ratio of tantalum or niobium on the first surface close to the seed crystal S becomes lower than that on the second surface opposite to the first surface.

In addition, for example, the concentration of tantalum or niobium on the surface of the raw material G may be higher than that inside the raw material G. For example, when the raw material G is divided into two parts in the height direction, tantalum or niobium may be added to only an upper layer which is a seed crystal side. When tantalum or niobium is present in the vicinity of the surface of the raw material G, it is possible to increase the efficiency of sublimation of tantalum or niobium.

In addition, for example, when the raw material G is viewed in a plan view, the concentration of tantalum or niobium at the center may be higher than that in the outer side. SiC gas flows from a high-temperature region to a low-temperature region. Since the crucible 10 is heated from the outside, the temperature of the outer side is higher than the temperature of the central part. That is, a portion of sublimated SiC gas flows from the outer side to the central part. In addition, when the sublimated SiC gas passes through a region in which the concentration of tantalum or niobium is high, a C/Si ratio can be adjusted appropriately.

In addition, for example, the raw material G may be divided into a portion formed of SiC and a portion formed of tantalum or niobium.

For example, tantalum or niobium may be deposited on the surface of a SiC raw material. Tantalum or niobium exists in the vicinity of the surface of the raw material G, and thus it is possible to increase the efficiency of sublimation of tantalum or niobium. In addition, a sublimated SiC gas passes through a layer formed of tantalum or niobium, and thus a C/Si ratio is adjusted appropriately.

In addition, for example, when the raw material G is viewed in a plan view, the central region may be filled with tantalum or niobium, and the outer circumferential region may be filled with SiC raw material. As described above, since a portion of the sublimated SiC gas flows from the outer side to the central part, tantalum or niobium is disposed at a position where the sublimated SiC gas passes through, and thus a C/Si ratio is adjusted appropriately.

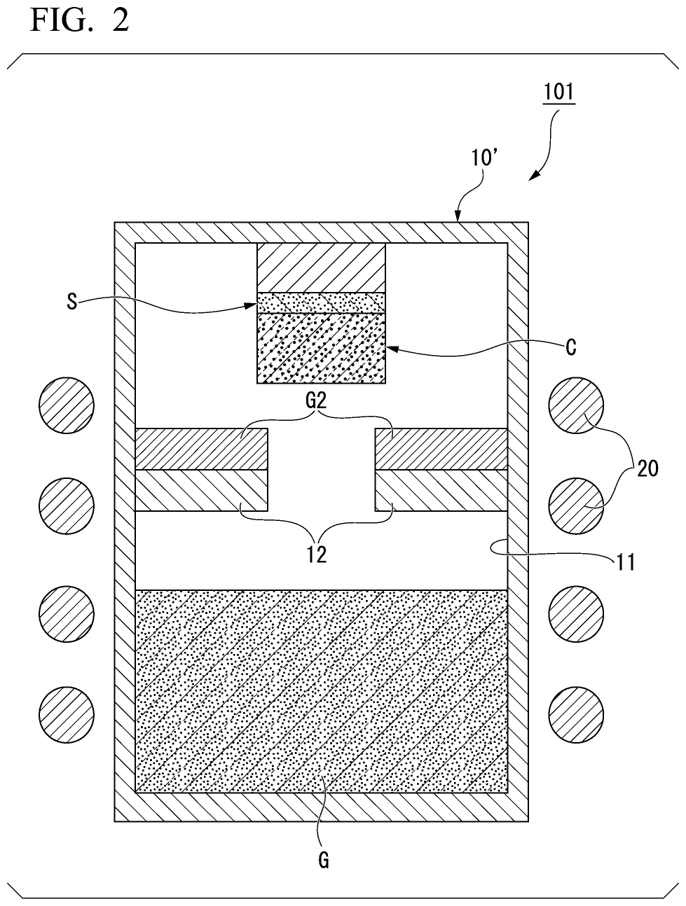

In addition, for example, tantalum or niobium may be installed in a portion other than the raw material G. FIG. 2 is a cross-sectional view of a SiC ingot manufacturing device 101 according to a modification example, and illustrates an example in which tantalum or niobium is installed in a portion other than a raw material G. FIG. 2 illustrates an example of a SiC ingot manufacturing step using a sublimation method. In the manufacturing device 101, the same components as those of the manufacturing device 100 are denoted by the same reference numerals and signs, and the description thereof will be omitted. A surface which is parallel to the axial direction of a crucible 10′ of the manufacturing device 101 will be referred to as an inner surface 11. The manufacturing device 101 includes a protrusion portion 12 that protrudes toward the axial center of the crucible 10′ from the inner surface 11.

For example, powder or plate-like tantalum or niobium may be installed at any position between the raw material G and a seed crystal S in the height direction. For example, powder or plate-like tantalum or niobium is installed on a protrusion portion 12 protruding toward the inner side from the inner surface 11 of the crucible. In FIG. 2, powder or plate-like tantalum or niobium to be installed is denoted by sign G2. The protrusion portion 12 on which tantalum or niobium is installed may have or may not have a portion overlapping the seed crystal S when seen in a plane view. The raw material G is sublimated on the environment in which tantalum or niobium is positioned between the raw material G and the seed crystal S. Tantalum or niobium is disposed at a position where a sublimated SiC gas passes through, and thus a C/Si ratio is adjusted appropriately.

### EXAMPLES

### Example 1

3 wt % of Ta powder was added to SiC raw material powder in which the content of Ta was a limit of detection or less, and the powder was placed in a crucible. In addition, a seed crystal was positioned at a position facing the raw material accommodated in the crucible, and the single crystal was grown by a sublimation method. The content of tantalum in the obtained single crystal was 5×10¹⁴ cm⁻³. The same experiment was performed 20 times. Thus, a single crystallization rate in Example 1 was obtained. The single crystallization rate is a rate at which heterogeneous polymorphism did not occur in the single crystal with respect to the number of experiments. The single crystallization rate in Example 1 was 95%.

### Example 2

Ta powder of 1 wt % was added to SiC raw material powder in which the content of Ta was a detection limit or less, and the powder was accommodated in a crucible. In addition, a seed crystal was installed at a position facing the raw material accommodated in the crucible, and the single crystal was grown by a sublimation method. The content of tantalum in the obtained single crystal was 3×10¹⁴ cm⁻³. The same experiment was performed 20 times. Then, a single crystallization rate in Example 2 was obtained. The single crystallization rate is a ratio at which heterogeneous polymorphism did not occur in the single crystal with respect to the number of experiments. The single crystallization rate in Example 2 was 90%.

### Example 3

Ta powder of 8 wt % was added to SiC raw material powder in which the content of Ta was a detection limit or less, and the powder was accommodated in a crucible. In addition, a seed crystal was installed at a position facing the raw material accommodated in the crucible, and the single crystal was grown by a sublimation method. The content of tantalum in the obtained single crystal was 1×10¹⁵ cm⁻³. The same experiment was performed 20 times. Then, a single crystallization rate in Example 3 was obtained. The single crystallization rate is a ratio at which heterogeneous polymorphism did not occur in the single crystal with respect to the number of experiments. The single crystallization rate in Example 3 was 90%.

### Comparative Example 1

Comparative example 1 is different from Example 1 in that a mass ratio of Ta powder to be added to SiC raw material powder in which the content of Ta is a detection limit or less is set to 10 wt %. The content of tantalum in the obtained single crystal was 2×10¹⁵ cm⁻³. The same experiment was performed 20 times. Then, a single crystallization rate in Comparative Example 1 was obtained. The single crystallization rate is a ratio at which heterogeneous polymorphism did not occur in the single crystal with respect to the number of experiments. The single crystallization rate in Comparative Example 1 was 80%.

### Comparative Example 2

Comparative Example 2 is different from Example 1 in that a mass ratio of Ta powder to be added to SiC raw material powder in which the content of Ta is a detection limit or less is set to 0.5 wt %. The content of tantalum in the obtained single crystal was 1×10¹⁴ cm⁻³. The same experiment was performed 20 times. Then, a single crystallization rate in Comparative Example 2 was obtained. The single crystallization rate is a ratio at which heterogeneous polymorphism did not occur in the single crystal with respect to the number of experiments. The single crystallization rate in Comparative Example 2 was 80%.

### EXPLANATION OF ELEMENTS

10, 10′: Crucible
11: Inner surface
12: Protrusion portion
20: Coil
100, 101: Manufacturing device
C: Single crystal (SiC single crystal)
G: Raw material
S: Seed crystal

What is claimed is:

1. A SiC substrate comprising:
tantalum or niobium of which a content is equal to or more than 3×10¹⁴ cm⁻³ and equal to or less than 1×10¹⁵ cm⁻³; and
nitrogen of which a content is equal to or more than 1×10¹⁶ cm⁻³ and equal to or less than 1×10²⁰ cm⁻³.

2. The SiC substrate according to claim 1, wherein
a content of aluminum is less than 1×10¹⁶ cm⁻³.

3. The SiC substrate according to claim 1, wherein
a content of boron is less than 1×10¹⁶ cm⁻³.

4. The SiC substrate according to claim 1, wherein
a content of a heavy metal element is less than 1×10¹⁴ cm⁻³.

5. The SiC substrate according to claim 1, wherein
content ratio of tantalum or niobium differ between those on a first surface and a second surface perpendicular to a thickness direction.

6. The SiC substrate according to claim 1, further comprising:
a first surface and a second surface perpendicular to a thickness direction,
wherein a content ratio of tantalum or niobium decreases toward the second surface from the first surface.

7. A SiC single crystal manufacturing method using a sublimation method in which a single crystal is grown by recrystallizing a gas sublimated from a raw material on a surface of a seed crystal, wherein
the raw material contains tantalum or niobium.

8. The SiC single crystal manufacturing method according to claim 7, wherein
a concentration of tantalum or niobium in the raw material is substantially constant.

9. The SiC single crystal manufacturing method according to claim 7, wherein
a concentration of tantalum or niobium on a surface of the raw material which faces the seed crystal is lower than a concentration of tantalum or niobium inside the raw material.

10. The SiC single crystal manufacturing method according to claim 7, wherein
the tantalum or niobium is deposited on a surface of a SiC raw material.

11. The SiC single crystal manufacturing method according to claim 7, wherein
a concentration of tantalum or niobium on a surface of the raw material which faces the seed crystal is higher than a concentration of tantalum or niobium inside the raw material.

12. The SiC single crystal manufacturing method according to claim 7, wherein
a concentration of tantalum or niobium at the center is higher than a concentration of tantalum or niobium in the outer side when the raw material is seen in a plan view.

13. The SiC single crystal manufacturing method according to claim 7, wherein
an amount of the tantalum or niobium added is equal to or more than 1 wt % and equal to or less than 8 wt %.

14. A SiC single crystal manufacturing method using a sublimation method in which a single crystal is grown by recrystallizing a gas sublimated from a raw material on a surface of a seed crystal, wherein
the raw material is sublimated on the environment in which powder or plate-like tantalum or niobium is positioned between the raw material and the seed crystal.

15. The SiC single crystal manufacturing method according to claim 14, wherein
the SiC single crystal manufacturing method is a SiC single crystal manufacturing method using a crucible including a protrusion portion that protrudes toward an axial center of the crucible from an inner surface, and
the raw material is sublimated on the environment in which the powder or plate-like tantalum or niobium is positioned on the protrusion portion.
